(19) United States
(12) Patent Application Publication
(10) Pub. No.: US 2025/0385088 A1
(43) Pub. Date: Dec. 18, 2025

(54) BACKSIDE LAYER FOR A SEMICONDUCTOR SUBSTRATE

(71) Applicant: Lam Research Corporation, Fremont, CA (US)

(72) Inventors: Soumana Hamma, Tigard, OR (US); Fayaz A. Shaikh, Lake Oswego, OR (US); Sonia Greninger, Mcminnville, OR (US)

(21) Appl. No.: 19/111,257

(22) PCT Filed: Sep. 11, 2023
(86) PCT No.: PCT/US2023/032425

§ 371 Date: Mar. 12, 2025

Related U.S. Application Data
(60) Provisional application No. 63/375,747, filed on Sep. 15, 2022.

(51) Int. Cl. H01L 21/02; C23C 16/02; C23C 16/24; C23C 16/455; C23C 16/507; C23C 16/52

(52) U.S. Cl. CPC H01L 21/02532; C23C 16/0272; C23C 16/24; C23C 16/45565; C23C 16/507; C23C 16/52; H01L 21/02592; H01L 21/02595; H01L 21/0262

(57) ABSTRACT

A composite nanocrystalline silicon layer can be formed by depositing a polycrystalline silicon sublayer directly or indirectly on a substrate. An amorphous silicon sublayer is deposited on the polycrystalline silicon sublayer. The composite nanocrystalline silicon layer can be formed by repeating the deposition of the polycrystalline silicon sublayer and the amorphous silicon sublayer.

### INCORPORATION BY REFERENCE

A PCT Request Form is filed concurrently with this specification as part of the present application. Each application that the present application claims benefit of or priority to as identified in the concurrently filed Application Data Sheet is incorporated by reference herein in their entireties and for all purposes.

### BACKGROUND

Certain semiconductor device fabrication operations require clamping or “chucking” a semiconductor wafer or substrate. In some cases, the operations use an electrostatic chuck (ESC). One example of such operation is in photolithography for transferring a pattern to a water.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided are methods of forming a composite nanocrystalline silicon sublayer. The method may include (a) depositing a polycrystalline silicon sublayer directly or indirectly on a substrate, and (b) depositing an amorphous silicon sublayers on the polycrystalline silicon sublayer, and (c) repeating (a) and (b) one or more times.

In some embodiments, the polycrystalline silicon sublayer may be deposited by chemical vapor deposition, plasma assisted chemical vapor deposition, atomic layer deposition, plasma assisted atomic layer deposition, or epitaxial growth.

In some embodiments, the amorphous silicon sublayer may be deposited by chemical vapor deposition, plasma assisted chemical vapor deposition, atomic layer deposition, plasma assisted atomic layer deposition, or epitaxial growth.

In some embodiments, (c) may be performed at least two times.

In some embodiments, the polycrystalline silicon sublayer and the amorphous silicon sublayer may be deposited on a backside of the substrate.

In some embodiments, the thickness ratio of the polycrystalline silicon sublayer to the amorphous silicon sublayer may be about 0.2 to 3.0.

In some embodiments, the thickness of the amorphous silicon sublayer may be about 5 to 50 nm.

In some embodiments, the thickness of the polycrystalline silicon sublayer may be about 5 to 50 nm.

In some embodiments, the amorphous silicon sublayer may be deposited at a temperature of about 200-600° C.

In some embodiments, the polycrystalline silicon sublayer may be deposited at a temperature of about 200-600° C.

In some embodiments, the amorphous silicon sublayer may be deposited at a pressure of about 1-9 Torr.

In some embodiments, the polycrystalline silicon sublayer may be deposited at a pressure of about 1-9 Torr.

In some embodiments, the amorphous silicon sublayer may be deposited at an RF power of about 100-500 watts per station.

In some embodiments, the polycrystalline silicon sublayer may be deposited at an RF power of about 100-500 watts per station.

In some embodiments, the amorphous silicon sublayer may be deposited at an RF frequency of about 13.56 MHz or about 27 MHz.

In some embodiments, the polycrystalline silicon sublayer may be deposited at an RF frequency of about 13.56 MHz or about 27 MHz.

In some embodiments, the composite nanocrystalline silicon layer may have a hardness of less than 9 GPa.

In some embodiments, the composite nanocrystalline silicon layer may have a surface roughness of about 0.2 to about 10 nm.

Another aspect of the disclosure relates to an apparatus. The apparatus may include a reaction chamber, a pedestal for supporting a substrate comprising a front side and a backside in the reaction chamber during a deposition process, a gas supply configured to deliver a silicon-containing precursor to the substrate while held by the pedestal, a radio frequency (RF) power supply for providing power to the showerhead to generate a plasma, and a controller. The controller is configured to cause: (a) deposit a polycrystalline silicon sublayer directly or indirectly on the substrate, (b) deposit an amorphous silicon sublayer on the polycrystalline silicon sublayer, and (c) repeat (a) and (b) one or more times.

In some embodiments, the gas supply may be fluidly coupled to the pedestal to deliver the silicon-containing precursor to the backside of the substrate.

In some embodiments, the pedestal may be configured to deposit the polycrystalline silicon sublayer or the amorphous silicon sublayer on the backside of the substrate.

In some embodiments, the polycrystalline silicon sublayer and the amorphous silicon sublayer may be deposited by a plasma enhanced chemical vapor deposition or a plasma enhanced atomic layer deposition.

Yet another aspect of the disclosure relates to a method. The method may include (a) forming a bow-compensating backside layer on substrate, wherein the backside layer has a surface roughness of about 1-4 nm, (b) attaching the substrate to a substrate support, and (c) performing a fabrication operation on the substrate while attached to the substrate support.

In some embodiments, the bow-compensating layer has a hardness of about 10 GPa or less.

In some embodiments, the substrate support is a clamp or a chuck.

In some embodiments, the substrate support is a lithography table for a UV or EUV lithography system.

Yet still another aspect of the disclosure relates to a substrate. The substrate includes a partially fabricated electronic device on the substrate. The substrate includes a semiconductor wafer. The frontside of the semiconductor wafer includes the partially fabricated electronic device. The substrate includes a backside layer on the semiconductor wafer. The backside layer is opposite the frontside. The backside layer includes a composite nanocrystalline silicon layer.

In some embodiments, the composite nanocrystalline silicon layer includes alternating layer of amorphous silicon and polycrystalline silicon.

In some embodiments, the semiconductor wafer is a single crystal silicon wafer.

These and other aspects are described further below with reference to the drawings.

### BRIEF DESCRIPTION OF THE DRAWINGS

FIG. 1 is a process flow diagram illustrating some embodiments.

FIGS. 2A-2E are schematic depictions of example cross section of a substrate during semiconductor processing according to some embodiments.

FIGS. 3A-3B show block diagrams of an example substrate processing chamber according to some embodiments.

FIG. 4 shows a schematic of an example process system that may be used to perform the methods according to some embodiments.

FIG. 5 is hardness measured for a-Si sublayer, a composite nanocrystalline silicon layer, a poly-Si sublayer, and silicon wafer according to some embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### Terminology

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, 300 mm, or 450 mm. Examples of wafer materials include silicon (Si), gallium arsenide (GaAs), and silicon germanium (SiGe). Besides semiconductor wafers, other workpieces that may take advantage of the disclosed embodiments include various articles such as printed circuit boards, magnetic recording media, magnetic recording sensors, mirrors, optical elements, display devices or components such as backplanes for pixelated display devices, flat-panel displays, micro-mechanical devices and the like. The workpiece may be of various shapes, sizes, and materials.

A “semiconductor device fabrication operation” as used herein is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

“Manufacturing equipment” refers to equipment in which a manufacturing process takes place. Manufacturing equipment often has a reaction chamber in which the workpiece resides during processing. Typically, when in use, manufacturing equipment performs one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers.

“Wafer bow” as used herein may refer to a deformation of a wafer. Wafer bow may occur during fabrication resulting from, for example, stress to the wafer during deposition of materials on an active surface of a wafer substrate. Wafer bow may occur during various types of fabrication, such as when large stacks of materials are deposited. Wafer bow may cause complications in subsequent processing steps. For example, the wafer may fail to chuck correctly if an amount of bowing is too large. Moreover, some processing steps, notably photolithography and etching, may produce poor results if performed on a wafer that is excessively bowed.

Wafer bow may be measured as a deviation of the mean or median distance of the surface of the wafer to a reference plane. The point of the median surface of the wafer may be the center point (e.g., in the case of concave or domed bowing), or an edge point of the wafer and/or an average edge point of the wafer (e.g., in the case of warping or convex bowing).

“Backside layer” as used herein refers to any layer formed on a on a side of a substrate that is opposite substrate's front side. The front side is where electronic devices are typically formed on semiconductor substrates such as single crystal silicon wafers. For many applications, a backside layer compensates wafer bow. A backside layer may be formed from any one of many possible materials. In some embodiments, the material is a composite nanocrystalline silicon layer including an amorphous silicon layer and a polycrystalline silicon layer. “Backside layer” may be characterized by certain physical properties such as a roughness and/or a hardness as disclosed herein.

An “electrostatic chuck” (ESC) as used herein refers to a chuck that uses electrostatic force to clamp a wafer to the chuck during processing. The ESC may use one or more electrodes. Voltages may be applied to each of the one or more electrodes. The applied voltage may cause current to flow, thereby causing charge to migrate through a dielectric layer between the chuck and a wafer or substrate being processed. Opposite charges accumulated at an electrode relative to the wafer therefore cause the wafer to be gripped or clamped to the chuck by the electrostatic force. In some cases, the electrodes may be integrated into the ESC, or may be separate from the ESC. In some embodiments, the ESC may refer to the electrodes the generate the electrostatic force.

A “pedestal” as used herein may refer to a structure or housing that supports or includes a chuck.

### Introduction and Context

Semiconductor device fabrication often involves deposition of a stack of layers on a wafer substrate. Typically, most deposition and other processing to form the devices occurs on one side of the substrate, often referred to as the front face of a wafer. As the deposited layers build up, they can introduce stress in the wafer. A large net compressive or tensile stress can cause the wafer to bow, which is undesirable.

Bowing is especially likely to occur where large stacks of materials are deposited, for example in the context of 3D-NAND devices. Where bowing is significant, it can deleteriously affect subsequent processing steps. For instance, the wafer may fail to chuck correctly if the bowing is too great. Further, certain processing steps (e.g., photolithography) are very precise and produce poor results if the wafer is not substantially flat. The problem may be manifest as lithography defocus and/or overlay problems.

One example stack that may cause these problems is a stack having alternating layers of oxide and nitride (e.g., silicon oxide/silicon nitride/silicon oxide/silicon nitride, etc.). Another example stack likely to cause bowing includes alternating layers of oxide and polysilicon (e.g., silicon oxide/polysilicon/silicon oxide/polysilicon, etc.). Other examples of stack materials that may be problematic include, but are not limited to, tungsten, titanium nitride, and carbon.

The materials in the stacks may be deposited through chemical vapor deposition techniques such as plasma enhanced chemical vapor deposition (PECVD), low pressure chemical vapor deposition (LPCVD), metal organic chemical vapor deposition (MOCVD), atomic layer deposition (ALD), plasma enhanced atomic layer deposition (PEALD), or through direct metal deposition (DMD), etc. These examples are not intended to be limiting. Certain disclosed embodiments may be useful whenever wafer stress and/or bowing are induced due to material present on the front side of the wafer.

Various techniques have been devised for combatting bowing. Many such techniques involve tuning deposition processes to reduce or counteract internal stresses in deposited layers. For example, some processes deposit a film on the backside of the wafer. Alternatively, electrostatic chucking (ESC) may be conducted in a manner that reduces or eliminates bowing (e.g., a clamped wafer exhibits less than about 150 μm of bow).

One widely used technique to combat bowing involves deposition of a high stress dielectric film using chemical vapor deposition (CVD) on the backside of a wafer. If the backside film has an internal stress that is of the same type and of comparable magnitude to the internal stress on the frontside, the backside film effectively counteracts and corrects the bow.

A typical scenario may involve the following:
1. deposit one or more frontside layers that have high internal stress that produce significant bowing (chamber A)
2. deposit a backside layer having internal stress that counteracts the internal stress of the one or more frontside layers and reduces or eliminates the bowing (chamber B)
3. pattern the frontside of the unbowed substrate by photolithography
4. etch the unbowed, patterned substrate (chamber C)
   Chambers A, B, and C may each be different, although this not always the case. For example, in some embodiments, chambers A and C are the same.

Lithography is a process used define feature patterns on integrated circuit layers. It dictates the shapes, dimensions, and locations of the different components of the integrated circuit. Integrated circuit makers have been able to extend the 193 nm lithography far beyond what was considered possible using complex multiple patterning techniques as device size shrinks. However, adding more and more optical steps is not sustainable as it leads to longer manufacturing cycle times, more risks on impacting yield. Further, the ability to figure out yield issues becomes extremely complex.

As a result, integrated circuit logic manufacturers are transitioning to Extreme Ultra-Violet Lithography (EUVL) starting at 5 nm technology node. With its 13.5 nm wavelength, EUVL can provide simplicity in patterning. However, enabling EUVL in HVM (high volume manufacturing) faces multiple challenges including cost and scanner uptime among others.

During patterning, as well as during many other processes, a wafer is to be maintained flat on a lithography table using an electrostatic chuck to prevent motion and minimize overlay errors associated with wafer warpage. Due to the strong forces involved in keeping the wafer flat during process, the electrostatic chuck may be damaged. Scratches and dents sometimes seen on the backsides of wafers from upstream processes may, over time, result in erosion and/or deformation on the lithography electrostatic chuck table surface. The erosion of the lithography table surface correlates to the hardness of the material on the back of the wafer. Such material is often a bow-compensating, silicon-containing backside layer.

The surface of lithography table is designed with precisely defined features to improve chucking and minimize overlay errors. If erosion of the surface occurs and chuck spots (localized uncorrectable overlay errors) cause significant yield loss, then lithography tables must be replaced. Because of these failures, the EUV lithography tables are usually replaced very frequently causing significant cost and uptime challenges.

In accordance with embodiments herein, a method of forming a composite nanocrystalline silicon layer is disclosed. The layer may have relatively low hardness in comparison to some other silicon layers, and it may have other beneficial properties. In some embodiments, the composite nanocrystalline silicon layer reduces the likelihood of damaging a chuck in a subsequent process. Such chucks include those used in any downstream process including lithography chuck tables. In some embodiments, the composite nanocrystalline silicon layer is employed as a bow-counteracting backside layer that may produce reduced or no damage when a substrate is clamped or chucked (e.g., electrostatically chucked) to a substrate supporting component such as a lithography table. In some embodiments, the composite nanocrystalline silicon layer with reduced hardness as described herein may be applied independently from or in combination with one or more other bow-counteracting backside layers on the backside of a substrate. For example, the composite nanocrystalline silicon layer may be deposited on or over a bow-counteracting backside layer including, e.g., a bow-compensating layer of silicon nitride and/or silicon oxide on the backside of the wafer.

### Deposition Process

Conventionally, a silicon layer may be deposited using a CVD, PECVD, ALD, PEALD, or epitaxial growth process. If the silicon layer is a backside layer, it may be deposited in a specially designed backside deposition apparatus such as the Vector DT® and Datum tools available from Lam Research Corp. of Fremont, CA.

Certain embodiments disclosed herein employ a cyclic approach of alternating deposition of layers of amorphous silicon (a-Si) and polycrystalline silicon (poly-Si) to create a composite nanocrystalline silicon layer. The composite nanocrystalline silicon layer may have a lower hardness than that of either of the constituent individual layers standing alone.

In some embodiments, the individual layers are deposited by PECVD or PEALD. When using plasma assisted deposition methods, the composite nanocrystalline silicon layer may be formed at a relatively low temperature (e.g., about 400° C. or lower), making the overall deposition process compatible with both front-end-of-line (FEOL) and back-end-of-line (BEOL) integrations flows. In some embodiments, the composite nanocrystalline silicon layer may be produced without using a post-deposition operation such as annealing. In other words, after the cyclic a-Si/poly-Si (or poly-Si/a-Si) process is completed, the resulting layer is ready to use, without any further processing.

In some embodiments, a composite nanocrystalline silicon layer is deposited using a tool that is designed to deposit material only on the backside of a substrate. An example of such tool the Vector DT® tool available from Lam Research, Corp. of Fremont, CA. In some embodiments, the composite nanocrystalline silicon layer may be produced without using a thermal process, such as a process that requires a furnace at an elevated temperature (e.g., about 650-850° C. or 700° C.). The deposition process such as CVD may require using a furnace that often deposits material over the entire substrate, including the backside, the frontside, and the bevel.

### Amorphous Silicon (a-Si) Sublayer

### Precursors

An amorphous silicon (a-Si) layer may be formed on the backside of a substrate by a low temperature process (e.g., PECVD or PEALD) by using one or more silicon-containing precursors. In some embodiments, silicon-containing precursors may include one or more Si—H bonds. In some cases, silicon-containing precursors include one or more Si—Si bonds. Silicon-containing precursors suitable for use in accordance with disclosed embodiments may include silanes, including polysilanes (H₃Si—(SiH₂)ₙ—SiH₃), where n>0. Examples of silanes include silane (SiH₄), disilane (Si₂H₆), trisilane (Si₃H₈), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

In some embodiments, a silicon-containing precursor may also include a halosilane. A halosilane includes at least one halogen atom and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

In some embodiments, silicon-containing precursors may also include an aminosilane. An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

In addition to the silicon-containing precursor, one or more carrier gas may be flowed to the environment adjacent to the substrate. Examples of the carrier gas include but not limited to helium (He), neon (Ne), argon (Ar), krypton (Kr), xenon (Xe), deuterium (D₂), hydrogen (H₂), and nitrogen (N₂). In some embodiments, a gas mixture of one or more source gases (e.g., a silicon-containing precursor) and one or more of the inert carrier gas may be provided. In some embodiments, the ratio of flow rate of silicon-containing precursor to carrier gas may range between about 1/1 and about 1/1,000, or between about 1/3 and about 1/300. In some embodiments, a-Si sublayer may be a hydrogenated amorphous silicon (a-Si:H) layer.

### Pressure

In some embodiments, the chamber pressure during the deposition of an a-Si sublayer may be about 1-9 Torr, or about 2-6 Torr, or about 3-5 Torr.

### Temperature

In some embodiments, the deposition temperature may be about 200-600° C., or about 250-450° C., or about 300-420° C., or about 350-400° C.

### Plasma Parameters

Where an a-Si sublayer is deposited by a plasma assisted deposition process (e.g., PECVD or PEALD), the plasma may be generated by applying radio frequency (RF) power to the process chamber. In some embodiments, the RF power has a high frequency (e.g., 13-40 MHz) and/or a low frequency (e.g., <1 MHz). In some embodiments, high frequency RF power is provided at a frequency of about 13.56 MHz or about 27 MHz. A plasma power (i.e., RF power) may be about 50 to 1,000 watts (W), or 100-500 W per wafer being processed (e.g., per station in a multi-station deposition chamber).

### Film Thickness

An a-Si sublayer formed according to some embodiments herein may have a thickness of about 5-50 nm, or about 10-20 nm.

Polycrystalline Silicon (poly-Si) Sublayer

### Precursor

A Poly-Si sublayer may be formed by providing one or more silicon-containing precursors to a substrate in a reaction chamber. In some embodiments, a silicon-containing precursor includes one or more Si—H bonds. In some embodiments, a silicon-containing precursor includes one or more Si—Si bonds. Silicon-containing precursors suitable for use in accordance with disclosed embodiments may include silanes, including polysilanes (H₃Si—(SiH₂)ₙ—SiH₃), where n≥0. Examples of silanes are silane (SiH₄), disilane (Si₂H₆), trisilane (Si₃H₈), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

In some embodiments, silicon-containing precursors may also include a halosilane. A halosilane includes at least one halogen atom and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

In some embodiments, silicon-containing precursors may also include an aminosilane. An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

In some embodiments, a silicon-containing precursor for poly-Si sublayer may be the same as a silicon-containing precursor for depositing a-Si sublayer. In some embodiments, different silicon-containing precursors may be provided in depositing poly-Si sublayer and a-Si sublayer.

In addition to the silicon-containing precursor, one or more carrier gas may be flowed to the environment adjacent to the substrate for depositing poly-Si sublayer. Examples of the carrier gas include but not limited to helium (He), neon (Ne), argon (Ar), krypton (Kr), xenon (Xe), deuterium (D₂), hydrogen (H₂), and nitrogen (N₂). In some embodiments, a gas mixture of one or more source gases and one or more of the inert carrier gases may be provided. Alternatively, a silicon-containing precursor and inert carrier gases may be separately provided into the reaction chamber. In some embodiments, the ratio of flow rate of silicon-containing precursor to carrier gas may range between about 1/1 and about 1/1,000, or between about 1/3 and about 1/300, or between about 1/100 and about 1/300.

### Pressure

In some embodiments, the chamber pressure during the deposition of poly-Si sublayer may be about 1-9 Torr, or about 2-6 Torr, or about 3-5 Torr.

### Temperature

In some embodiments, the deposition temperature may be about 200-600° C., or about 250-450° C., or about 300-420° C., or about 350-400° C.

### Plasma Parameters

Where a poly-Si sublayer is deposited by a plasma assisted deposition process (e.g., PECVD or PEALD), the plasma may be generated by applying radio frequency (RF) power to the process chamber. In some embodiments, the RF power has a high frequency (e.g., 13-40 MHz) and/or a low frequency (e.g., <1 MHz). In some embodiments, high frequency RF power is provided at a frequency of about 13.56 MHz or about 27 MHz. A plasma power (i.e., RF power) may be about 50 to 1,000 watts (W), or 100 to 500 W per wafer being processed (e.g., per station in a multi-station deposition chamber).

### Film Thickness

A poly-Si sublayer formed according to some embodiments herein has a thickness of about 5-50 nm, or about 10-20 nm.

### Composite Nanocrystalline Silicon Layer Formation

A composite nanocrystalline silicon layer may be formed by alternatingly depositing an a-Si sublayer and a poly-Si sublayer on a substrate. The substrate may include a front side and a backside. In some embodiments, the front side of the substrate is patterned. A patterned substate may have “features” such as pillars, poles, trenches, vias or contact holes, which may be characterized by one or more of narrow and/or re-entrant openings, constrictions within the feature, and high aspect ratios. The feature(s) may be formed in one or more of the layers of materials, such as dielectric, conducting, or semiconducting material deposited thereon. In some embodiment, the front side of the substrate does not include any features. In some embodiments, a composite nanocrystalline silicon layer may be formed on the backside of the substrate.

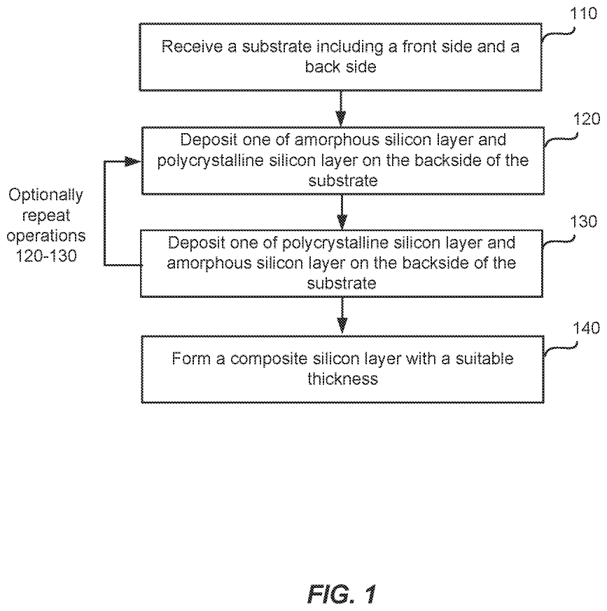

FIG. 1 presents a process flow diagram according to some embodiments. The process flow diagram illustrates some embodiments of forming a composite nanocrystalline silicon layer with a controlled hardness and/or a controlled surface roughness on the backside of the substrate. In one example, the process flow diagram describes some embodiments of forming a soft composite nanocrystalline silicon layer that prevents damaging the clamping surface of an electrostatic chuck (ESC).

In an operation 110, a substate including a front side and a backside may be received in a reaction chamber. In some embodiments, the substrate may include one or more features formed on the front side of the substrate. The features may be patterned or non-patterned thin films of metals, oxides, nitrides, carbides, or the like. In some embodiments, no feature may be formed on the front side of the substrate. In some embodiments, the backside of the substrate may be free of any features. In some embodiments, the backside of the substrate may have a higher surface roughness than the front side of the ide of the substrate.

In an operation 120, one of a poly-Si sublayer or an a-Si sublayer may be deposited by CVD, PECVD, ALD, PEALD, or epitaxial growth process on the backside of the substrate. The thickness of the poly-Si or the a-Si sublayer on the backside of the substrate may be about 5-50 nm, or about 10-20 nm. The ratio of flow rates of silicon-containing precursor to one or more carrier gas may be correlated with a resulting film property such as crystallinity of the layer. In some embodiments, a lower ratio of flow rates of silicon-containing precursor to one or more carrier gas may lead to the formation of a poly-Si layer with a columnar grain growth. A higher ratio of flow rates may lead to the formation of an a-Si layer with non-directional, random grain growth. For example, when the ratio of flow rates of silicon-containing precursor to one or more carrier gas such as hydrogen is low, the amount of hydrogen incorporated in the amorphous silicon increases up to the solubility limit. Beyond the solubility limit, reactions may be primarily based on hydrogen-hydrogen recombination that may be highly exothermic, and the energy may be released locally in a small area to favor the formation of silicon crystal nuclei. Once the nucleation is initiated, the crystal growth may follow.

After operation 120, one or more purge gases may be optionally provided to a reaction chamber to remove any excess precursors and/or other carrier gases in the operation 120 from the reaction chamber. Alternately, after completion of operation 120, operation 130 may be conducted immediately after modifying the deposition parameters (e.g., flow rate of precursors, pressure, temperature, plasma power, plasma frequency etc) for operation 130 without purging the reaction chamber.

In an operation 130, one of the a-Si sublayer or the poly-Si sublayer may be deposited on the poly-Si sublayer or the a-Si sublayer formed in the operation 120 to form an alternating two layered stack. For example, an a-Si sublayer may be deposited at operation 130 after a poly-Si sublayer is deposited in operation 120. In another example, a poly-Si sublayer may be deposited at operation 130 after an a-Si sublayer is deposited at operation 120. The a-Si sublayer or the poly-Si sublayer at operation 130 may be deposited by CVD, PECVD, ALD, PEALD, or epitaxial growth process. The thickness of the a-Si sublayer or the poly-Si sublayer formed at operation 130 may be about 5-50 nm, or about 10-20 nm.

The operations 120 and 130 may be repeated until the thickness of the composite nanocrystalline silicon layer reaches a predetermined thickness to form a composite nanocrystalline silicon layer at operation 140. In some embodiments, operations 120 and 130 may be repeated two times, or 5-10 times to adjust thickness of the composite nanocrystalline layer ranging about 50-200 nm, or about 70-150 nm. In other embodiments, operations 120 and 130 may be repeated 5-20 times until the thickness of a composite nanocrystalline layer ranges about 100-700 nm, or about 200-500, or about 300-400 nm. In some embodiments, the composite nanocrystalline silicon layer may include same numbers of a-Si sublayers and poly-Si sublayers. For example, the first layer directly deposited on the backside of the substrate may be a poly-Si sublayer, and the uppermost layer of the composite nanocrystalline silicon layer may be an a-Si sublayer. In other embodiments, the composite nanocrystalline silicon layer may include different numbers of a-Si sublayers and poly-Si sublayers.

In operations 120 and 130, the deposition parameters for a-Si sublayers and poly-Si sublayers may be configured to control the thickness of each of a-Si sublayers and poly-Si sublayers in a composite nanocrystalline silicon layer. In one example, the thickness of each of a-Si sublayers may be same or substantially same in a composite nanocrystalline silicon layer. In another example, the thickness of each of poly-Si sublayers may be same or substantially same in a composite nanocrystalline silicon layer.

In some implementations, the process can be tuned to adjust the hardness of the composite nanocrystalline silicon layer. For example, the hardness of the resulting composite nanocrystalline silicon layer may be tuned to a value that is up to 40% lower than that of a PECVD-formed a-Si sublayer or that of poly-Si sublayer. A composite nanocrystalline silicon layer can be deposited under conditions that produce a relatively high surface roughness compared to a-Si or crystalline silicon substrate.

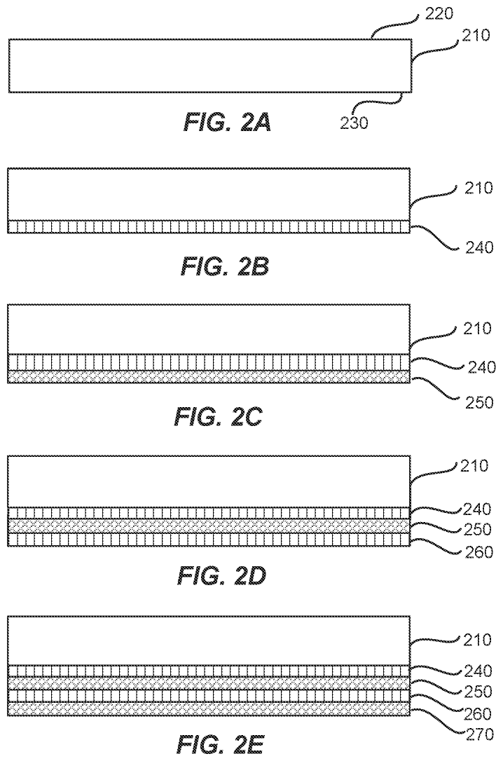

FIGS. 2A-2E show example cross sections of a substrate 200 after different operations according to some embodiments. FIG. 2A shows the cross section of the substrate 200 after received in a reaction chamber for backside deposition. One or more layers may be already formed on a frontside 220 of the substrate 200 prior to an operation according to some embodiments. The one or more layers may include features such as pillars, poles, trenches, vias or contact holes, which may be characterized by one or more of narrow and/or re-entrant openings, constrictions within the feature, and high aspect ratios. The feature(s) may be formed in one or more of the layers of materials, such as dielectric, conducting, or semiconducting material deposited thereon. The backside 230 of the substrate 210 may not be deposited by any layer prior to depositing an a-Si sublayer or a poly-Si sublayer according to some embodiments.

FIG. 2B shows the substrate 210 after a poly-Si sublayer 240 is deposited on the backside 230 of the substrate 210. The poly-Si sublayer 240 may be deposited on the substrate with a columnar grain growth extending in a direction perpendicular to the substrate. While FIG. 2B shows the poly-Si sublayer 240 formed as the first layer deposited directly on the backside 230 of the substrate, in other embodiments, a-Si sublayer may be formed as the first layer on the backside of the substrate 210.

FIG. 2C shows the substrate 200 after an a-Si sublayer 250 is deposited on the poly-Si sublayer 240 to form an alternating layers of poly-Si sublayer 240 and a-Si sublayer 250 on the substrate 210. Crystallites in the a-Si sublayer 250 may be amorphous and may not show any consistent directional growth on the poly-Si sublayer 240. The columnar grain growth of the poly-Si sublayer 240 may be at least in part stopped by the a-Si sublayer 250. The a-Si sublayer 250 may also provide reduced surface roughness.

FIG. 2D shows the substrate 200 after another poly-Si sublayer 260 is deposited on the a-Si sublayer 250. The columnar grain growth of poly-Si sublayer 260 may resume on the a-Si sublayer 250 which does not have any directional grain growth. In some embodiments, the columnar grain grown in the poly-Si sublayer 260 may not be as significant as the columnar grain growth in the poly-Si sublayer 240. FIG. 2E shows the substrate 200 including alternating layers of poly-Si sublayer 240, and a-Si sublayer 250, and poly-Si sublayer 260. An a-Si sublayer 270 may be formed on the poly-Si sublayer 260. Optionally alternating depositions of poly-Si sublayer and a-Si sublayer may be repeated until the desired thickness of a composite nanocrystalline silicon layer is obtained to form a composite nanocrystalline silicon layer.

### Composite Nanocrystalline Silicon Layer Properties

A composite nanocrystalline silicon layer produced using a cyclic process as described herein may possess one or more properties of interest. For example, a composite nanocrystalline silicon layer may have a relatively low hardness and/or a specifically tuned roughness. As mentioned, a composite nanocrystalline silicon layer may have hardness that is lower than the hardness of an a-Si sublayer produced using only the a-Si sublayer process described herein or a poly-Si sublayer produced using only the poly-Si sublayer process described herein.

### Hardness

The hardness of a composite nanocrystalline silicon layer may be determined using any of various techniques. Unless otherwise stated, the hardness values presented herein may be determined by a nanoindentation technique (e.g., Nanomechanical Test System, Hysitron, Inc, USA) performed on a composite nanocrystalline silicon films with about 650 nm thickness. Forces of 1050, 1200, and 1250 μN are applied to an indenter tip (Diamond Berkovich indenter tip) while measuring tip displacement into the composite nanocrystalline silicon film specimen. From a load-displacement curve obtained for each load, hardness (i.e., nanohardness) can be determined by applying the Oliver and Pharr method and a pre-calibrated indenter tip area function and a pre-determined machine compliance value. In certain embodiments, the hardness of the composite nanocrystalline silicon layer is about 10 GPa or less, or about 9 GPa or less, or about 8 GPa or less. In certain embodiments, the hardness (or average normalized hardness for multiple specimens) is less than about 0.80, or less than about 0.75, or less than about 0.65 with respect to silicon substrate having a hardness value of 1.0.

The hardness of the composite nanocrystalline silicon layer was lower than either of a-Si sublayer or poly-Si sublayer that was grown by PECVD or PEALD as described in the Examples section. While not limited to any mechanism or theory, the following is offered to explain why a composite nanocrystalline silicon layer may have a lower hardness than that of either of the constituent individual layers standing alone. When poly-Si crystallite growth is interrupted by depositing a-Si layer, the poly-Si crystallites that grows on the a-Si layer do not grow in a consistently columnar form. Because of this, the poly-Si crystallites grow in more random directions, which results in a layer that exhibits lower hardness than poly-Si sublayers deposited in a non-cyclic fashion. In some embodiments, the hardness of the composite nanocrystalline silicon layer may be tuned with respect to the thickness ratio of a-Si sublayer to poly-Si sublayer in the composite nanocrystalline silicon layer. For example, the thickness ratio of the a-Si sublayers to the poly-Si sublayers may be about 0.2 to 3.0, or about 0.3 to 2.5, or about 0.5 to 2.0.

### Roughness

The surface roughness for a composite nanocrystalline silicon layer may be measured by in-situ scanning probe microscopy (SPM) images obtained over an area of 3 μm×3 μm. The surface roughness may be determined in units of Ra, which is an arithmetic average of the absolute values of the profile height deviations from the mean line, recorded within the evaluation length. In certain embodiments, the Ra for the composite nanocrystalline silicon layer is about 0.2-10 nm, or about 1-4 nm. Typically, the Ra for a-Si sublayer is about 0.2-3 nm. Typically, the Ra for a poly-Si sublayer is about 0.2-10 nm. The Ra may be tuned by the thickness ratio of a-Si sublayer to poly-Si sublayer. For example, a low Ra for a composite nanocrystalline silicon layer may be obtained when the thickness ratio of a-Si sublayer to poly-Si sublayer increases, and Ra may be high for a composite nanocrystalline silicon layer having a low thickness ratio.

### Thickness

Depending on the application, the composite nanocrystalline silicon layer may be about 1-1000mm thick, or about 20-800 nm thick, or about 100-700 nm thick, or about 200-500 nm thick. For protecting a table surface of an ESC, the composite nanocrystalline silicon layer may have a thickness of about 100-700 nm, or about 200-500 nm on the backside of the substrate by, e.g., PECVD or PEALD according to some embodiments herein. In certain embodiments, a composite nanocrystalline silicon layer with a suitable thickness may be formed by repeating the deposition of a-Si sublayers and poly-Si sublayers by 5-20 times.

### Grain Size

The composite nanocrystalline silicon layer may have an average grain size of about 1-100 nm, or about 2-80 nm, or about 3-60 nm, or about 4-40 nm, or about 5-20 nm. The grain size may be measured by low angle x-ray diffraction (XRD; Bruker Semiconductor division, USA).

### Chemical Composition

In certain embodiments, a composite nanocrystalline silicon layer may include, in addition to the silicon (Si), hydrogen (H), nitrogen (N), and/or oxygen (O). H, N, and O may be from one or more carrier gases in depositing a-Si sublayer or poly-Si sublayer. In certain embodiments, the concentration of silicon is at least about 50% by mass. Qualitative analysis for a composite nanocrystalline silicon layer may be conducted by secondary-ion mass spectrometry (SIMS; EAG Laboratories, USA).

### Applications

The deposition methods and composite nanocrystalline silicon layers described herein can be used in many applications. Some of these applications use a composite nanocrystalline silicon layer as a backside layer on a substrate used in semiconductor device fabrication. As explained, such layer can compensate bow created by internal stress on the frontside of a substrate. In some cases, the semiconductor devices fabricated using backside layers are logic devices, and in some cases, the devices are memory devices such as NAND and DRAM memories. Backside layers may be deposited on wafers that undergo various downstream process including, but not limited to, lithography, etching, deposition, and polishing. In some embodiments, the semiconductor devices have critical dimensions of about 50 nm or less, about 20 nm or less, or about 10 nm or less.

In certain embodiments, a composite nanocrystalline silicon layer as a backside protective layer is used in UV or EUV lithography. Using such a composite nanocrystalline silicon layer as backside protective layer can significantly increase the lifetime of lithography tables in semiconductor device manufacturing, which can bring significant cost saving in processes employing EUV patterning.

Other applications and processes for substrates having composite nanocrystalline silicon backside layers include all applications that may employ a bow-compensating backside layer. These include etching processes, polishing applications, and deposition processes.

As noted, a composite nanocrystalline silicon layer has a carefully controlled roughness. In some contexts, higher backside roughness has been shown to improve overlay. For some applications, a composite nanocrystalline silicon layer may have a roughness of about 0.2-10 nm, or about 1-4 nm.

While most of this discussion has focused on applications that use composite nanocrystalline silicon as a backside layer, composite nanocrystalline silicon layers may also be used as a frontside material. For example, composite nanocrystalline silicon as described herein may be used for transistor gates, contacts, dummy structures for subsequent removal by etching, and the like. In other embodiments, MEMS (Micro-Electro-Mechanical Systems) with features (e.g., cantilevers) requiring silicon having particular mechanical and/or electrical properties may be produced by the methods herein. Poly-Si MEMS structures may require an elastic modulus and hardness in ranges disclosed herein.

The disclosed deposition methods and composite nanocrystalline silicon layers are not limited the applications listed here. The composite nanocrystalline silicon layers described herein can be employed in any application where film hardness modulation may be useful.

While the discussion to this point has focused on composite nanocrystalline silicon layers as the bow-compensating layers that provide protection against damage to substrate support components in downstream processes, aspects of this disclosure pertain to other materials that can provide a similar combination of benefits; that is bow-compensation along with protection of substrate support components. In some embodiments, a backside bow-compensating layer-which may be made from any material-has a roughness (Ra) of about 1-4 nm. Note that this roughness is on the side of the layer that will engage a chuck or other substrate support component such as a lithography wafer table. In some further embodiments, the backside bow-compensating layer has a hardness of about 9 GPa or less. Examples of materials that can provide backside layers having such properties include layers including various metals and metal compounds such as metal oxides, metal nitrides, metal carbides, and the like.

Substrates having backside layers with a roughness of about 1-4 nm (and optionally a hardness of about 9 GPa or less) may be employed in many different applications involving chucking, clamping, or other support of substrates in downstream processes. As mentioned, such processes may be deposition processes, etching processes, polishing processes, lithography processes, etc. One downstream process of interest is UV or EUV lithography. Such processes involve substrate supports that contain alignment marks. Often a substrate is slightly misaligned to a lithography table (sometimes referred to as a lithography wafer table or just a wafer table), and this misalignment is referred to as overlay error. Typically, over the life of a lithography table—as it supports thousands of substrates—overlay error degrades, e.g., from about 0.1 nm to 3-4 nm. It has been found that substrates having backside layers with a surface roughness value of about 1-4 nm can counteract this degradation in overlay error. For example, conducting UV or EUV lithography on substrates having bow-compensating backside layers with roughness values of about 1-4 nm preserves the performance of the associated lithography table, in particular it reduces overlay error degradation over time. It is believed that burls provided on the substrate-engaging surfaces of UV or EUV lithography tables wear down over time. Substrates having bow-compensating layers with a surface roughness as described may counteract the increased overlay error that would otherwise be caused by wearing down the burls.

In general, an integration process may include the operations of: (a) forming a bow-compensating backside layer on substrate, where the backside layer has a surface roughness of about 1-4 nm, (b) attaching the substrate to a substrate support, and (c) performing a fabrication operation on the substrate while attached the substrate support. In certain embodiments, the bow-compensating layer has a hardness of about 10 GPa or less. In certain embodiments, the substrate support is a lithography table for a UV or EUV lithography system.

### Apparatus

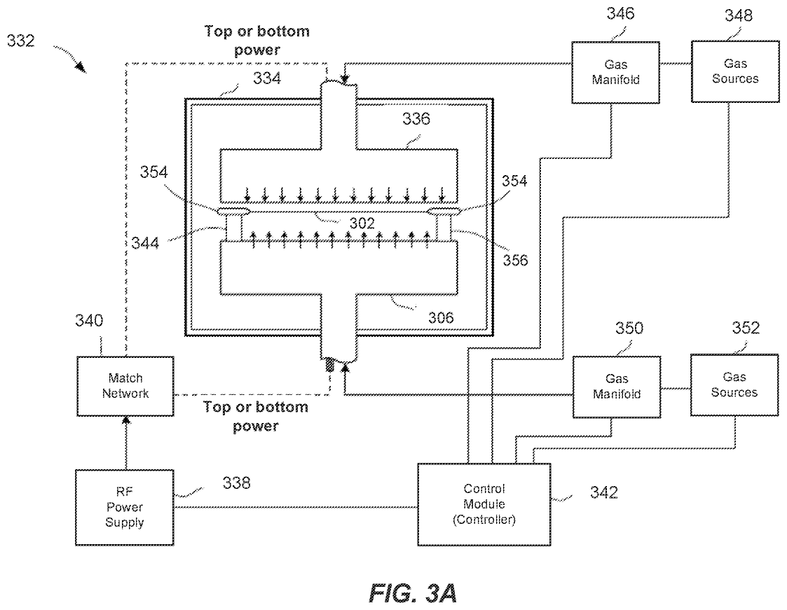

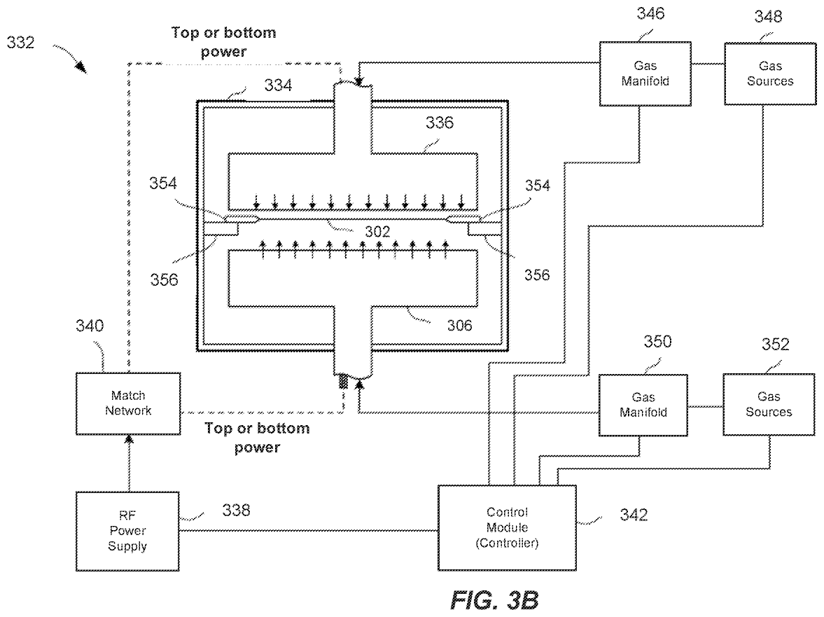

FIG. 3A is a block diagram that illustrates a substrate processing system 332 used to perform processing on a wafer 302 according to some embodiments. As shown, the substrate processing system may include a chamber 334. A center column may be configured to support a pedestal on which the wafer 302 is being processed, e.g., a film is being formed on the top surface of the wafer 302, or on the backside of the wafer 302. The pedestal, in accordance with some embodiments disclosed herein, may be referred to as a showerhead-pedestal (“ShoPed”) 306. A showerhead 336 may be disposed over the ShoPed 306.

In some embodiments, the showerhead 336 may be electrically coupled to power supply 338 via a match network 340 for powering a plasma. The power supply 338 may be controlled by a control module 342, e.g., a controller. In some embodiments, power may be provided to the ShoPed 306 instead of the showerhead 336. The control module 342 may be configured to operate the substrate processing system 332 by executing process input and control for specific process recipes. Depending on whether the top surface of the wafer 302 is receiving a deposited film or the bottom surface of the wafer 302 is receiving a deposited film, the controller module 342 may set various operational inputs for a process recipe, such as power levels, timing parameters, process gasses, mechanical movement of a wafer 302, and/or the height of the wafer 302 relative to the ShoPed 306.

In some embodiments, the plasma energy may be controlled by controlling one or more of the chamber pressure, a gas concentration, a RF source power, a RF source frequency, and a plasma power pulse timing. For example, RF power supply 338 and matching network 340 may be operated at any suitable power to form a plasma having a desired composition of radical species. Examples of suitable RF power ranges may be about 50-1,000 watts (W), or 100-500 W per station. Likewise, RF power supply 338 may provide RF power of any suitable frequency. In some embodiments, RF power supply 338 may be configured to control high- and low-frequency RF power sources independently of one another. Example low-frequency RF frequencies may include, but are not limited to, frequencies less than 1 MHz, or between 50 kHz and 600 kHz. Example high-frequency RF frequencies may include, but are not limited to, frequencies between 1.8 MHz and 2.45 GHz. In some embodiments, high-frequency of 13.56 MHz or about 27 MHz may be provided. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the center column may also include lift pins, which are controlled by a lift pin control. Such lift pins may be used to raise the wafer 302 from the ShoPed 306 to allow an end effector (not shown) to pick the wafer and to lower the wafer 302 after being placed by the end effector. The end effector may also place the wafer 302 over spacers 344. As will be described below, the spacers 344 may be sized to provide a controlled separation of the wafer 302 between a top surface of the showerhead 336 (facing the wafer) and a top surface of the ShoPed 306 (facing the wafer).

In some embodiments, the substrate processing system 332 may further include a first gas supply including a first gas manifold 346 that is connected to first gas sources 348, e.g., gas chemistry supplies from a facility and/or inert gases. For example, the gas chemistry supplies may include one or more silicon-containing precursors described herein and one or more carrier gases. Examples of the carrier gas include, but not limited to helium (He), neon (Ne), argon (Ar), krypton (Kr), xenon (Xe), deuterium (D₂), hydrogen (H₂), and nitrogen (N₂). Depending on the processing being performed over a top surface of the wafer 302, the control module 342 may controls the delivery of first gas sources 348 via the first gas manifold 346. The chosen gases may then be flown into the showerhead 336 and distributed in a space volume defined between a face of the showerhead 336 that faces that wafer 302 when the wafer is resting over the pedestal and the wafer 302.

In some embodiments, the substrate processing system 332 may further include a second gas supply including a second gas manifold 350 that is connected to second gas sources 352, e.g., gas chemistry supplies from a facility and/or inert gases. For example, the gas chemistry supplies may include one or more silicon-containing precursors described herein and one or more carrier gases. Examples of the carrier gas include, but not limited to helium (He), neon (Ne), argon (Ar), krypton (Kr), xenon (Xe), deuterium (D₂), hydrogen (H₂), and nitrogen (N₂). Depending on the processing being performed over a bottom surface of the wafer 302, the control module 342 may control the delivery of second gas sources 352 via the second gas manifold 350. The chosen gases may then be flown into the shower-ped 306 and distributed in a space volume defined between a face of the ShoPed 306 that faces an backside or under side (e.g., backside) of the wafer 302 and the wafer 302 when the wafer is resting over the spacers 344. The spacers 344 may provide for a separation that optimizes deposition to the backside of the wafer 302, while reducing deposition over the top surface of the wafer 302. In some embodiments, while deposition is targeted for the backside of the wafer 302, an inert gas may be flown over the top surface of the wafer 302 via the showerhead 336, which may push reactant gases away from the top surface and enable reactant gases provided from the ShoPed 306 to be directed to the backside of the wafer 302.

Further, the gases may be premixed or not. Appropriate valving and mass flow control mechanisms may be employed to ensure that the correct gases are delivered during the deposition and plasma treatment phases of the process. Process gases may exit the chamber 334 via an outlet. A vacuum pump (e.g., a one or two stage mechanical dry pump and/or a turbomolecular pump) may draw process gases out and maintains a suitably low pressure within the reactor by a close loop controlled flow restriction device, such as a throttle valve or a pendulum valve.

In some embodiments, a carrier ring 354 may encircle an outer region of the ShoPed 306. When the top surface of the wafer 302 is being processed, e.g., a material is being deposited thereon, the carrier ring 354 may be configured to sit over a carrier ring support region that is a step down from a wafer support region in the center of the pedestal ShoPed 306. The top surface of the carrier ring 354 may be generally coplanar with the top surface of the wafer 302. The carrier ring 354 may include an outer edge side of its disk structure, e.g., outer radius, and a wafer edge side of its disk structure, e.g., inner radius, that is closest to where the wafer 302 sits. The wafer edge side of the carrier ring 354 may also include a plurality of contact support structures or “tabs” which may be configured to lift the wafer 302 when the carrier ring 354 is held by the spacers 344. The carrier ring 354 may include a plurality of tabs with a quantity selected from a range to support the wafer 302 during processing. Additional details regarding embodiments of the tabs will follow.

FIG. 3B is a block diagram that illustrates another substrate processing system 332 used to perform processing on the wafer 302, according to some embodiments. In some embodiments, spider forks 356 may be used to lift and maintain the carrier ring 354 in its process height, e.g., to allow depositing in the backside of the wafer 302. The carrier ring 354 may therefore be lifted along with the wafer 302. In some implementations, the carrier ring 354 may be rotated to another station, e.g., in a multi-station system.

Broadly speaking, the embodiments disclosed herein are for a system to deposit PECVD films on the selective side of the wafer (front and/or back) with dynamic control. Some embodiments may include a dual gas-flowing electrode for defining a capacitively-coupled PECVD system. The system may include a gas-flowing showerhead 336 and a ShoPed 36. In some embodiments, the gas-flowing pedestal (i.e., ShoPed) is a combination showerhead and pedestal, which enables deposition on a backside of the wafer. The electrode geometry combines features of a showerhead, e.g., a gas mixing plenum, holes, hole-pattern, gas jet preventing baffle, and features of a pedestal. Examples of features of a pedestal include an embedded controlled heater, wafer-lift mechanisms, ability to hold plasma suppression rings, and movability. This enables the transfer of wafers and the processing of gasses with or without RF power from the pedestal.

In some embodiments, the system may have a wafer lift mechanism that tightly controls parallelism of the substrates against the electrodes. In one example, this may be achieved by setting up the lift mechanism parallel to the two electrodes and controlling manufacturing tolerances, e.g., spindle or lift pins mechanisms. In another example, the lift may be achieved by raising the wafer lift parts. This option may not allow dynamic control of the side that gets deposited.

In some configurations, the lift mechanism may allow dynamically controlling the substrate position during processing (before plasma, during plasma, after plasma) to control the side of the deposition, profile of the deposition, and properties of deposited film. The system may further allow selective enabling/disabling of the side where reactants are flown. One side can flow the reactant and the other side can flow inert gases to suppress the deposition and plasma.

In some embodiments, the gap between the side of the wafer that does not need plasma/dep may be tightly controlled. This distance may be controlled to suppress plasma. By not controlling the distance, the wafer may be susceptible to plasma damage. For example, the system may allow a minimal gap from about 2 mm to about 0.5 mm, and in another embodiment from about 1 mm to about 0.05 (limited by the wafer bow), and such gap can be controlled. The gap may be controlled depending on process conditions.

In some embodiments, the gas-flowing pedestal (i.e., ShoPed) may enable, without limitation: (a) thermal stabilization of the wafer to processing temperature prior to processing; (b) selective design of hole patterns on the ShoPed to selectively deposition film in different areas of the back-side of the wafer; (c) swappable rings can be attached to achieve appropriate plasma confinement and hole pattern; (d) stable wafer transfer mechanisms within chamber and for transferring wafer outside to another chamber or cassette-such as lift pins, RF-coupling features, minimum-contact arrays; (e) implement gas mixing features, e.g., such as inner plenum, baffle and manifold lines openings; and (f) add compartments in the gas-flowing pedestal (i.e., ShoPed) to enable selective gas flow to different regions of the backside of the wafer and control flow rates via flow controllers and/or multiple plenums.

In another embodiment, dynamic gap control using wafer lift mechanism enables: (a) control of the distance from deposition or reactant flowing electrode to the side of the wafer that needs deposition or in the middle so that both sides can be deposited; and (b) the lift mechanism to control the distance dynamically during the process (before plasma, during plasma, after plasma) to control the side of the deposition, profile of the deposition, and deposition film properties. In another embodiment, for a deposition mode used to deposit on the backside of the wafer, film edge exclusion control is highly desirable to avoid lithography-related overlay problems. The lift mechanism used in this system is done via a carrier ring 354 that has a design feature to shadow the deposition on the edge. This specifies the edge exclusion control via the design and shape of the carrier ring.

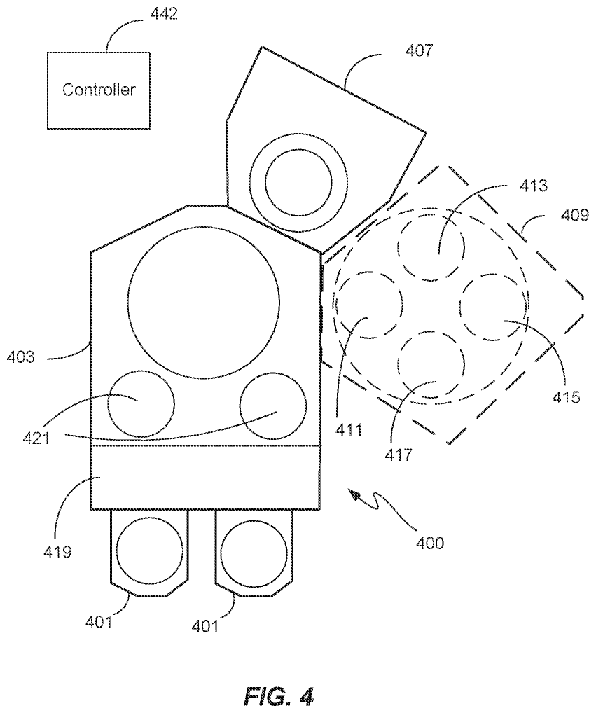

FIG. 4 is a schematic of a process system suitable for conducting deposition processes in accordance with embodiments. The system 400 includes a transfer module 403. The transfer module 403 provides a clean, pressurized environment to minimize risk of contamination of substrates being processed as they are moved between various reactor modules. Mounted on the transfer module 403 is a multi-station reactor 409 capable of performing ALD, treatment, and CVD according to various embodiments. Multi-station reactor 409 may include multiple stations 411, 413, 415, and 417 that may sequentially perform operations in accordance with disclosed embodiments. For example, multi-station reactor 409 may be configured such that station 411 performs a backside deposition of poly-Si sublayer by PECVD or PEALD, station 413 performs a backside deposition of a-Si sublayer by PECVD or PEALD, station 415 performs a first front side deposition of Si-based film by PECVD or PEALD, and station 417 may perform a second front side deposition of Si-based film by PECVD or PEALD. Stations may include a heated pedestal or substrate support, one or more gas inlets or showerhead or dispersion plate.

Returning to FIG. 4, also mounted on the transfer module 403 may be one or more single or multi-station modules 407 capable of performing plasma or chemical (non-plasma) pre-cleans, other deposition operations, or etch operations. The module may also be used for various treatments to, for example, prepare a substrate for a deposition process. The system 400 may also include one or more wafer source modules 401, where wafers are stored before and after processing. An atmospheric robot (not shown) in the atmospheric transfer chamber 419 may first remove wafers from the source modules 501 to loadlocks 421. A wafer transfer device (generally a robot arm unit) in the transfer module 503 may move the wafers from loadlocks 421 to and among the modules mounted on the transfer module 403.

In various embodiments, a system controller 442 is employed to control process conditions during deposition. The system controller 442 will typically include one or more memory devices and one or more processors. A processor may include a CPU or computer, analog and/or digital input/output connections, stepper motor controller boards, etc.

The system controller 442 may control all the activities of the deposition apparatus. The system controller 442 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the system controller 442 may be employed in some embodiments. For example, the system controller 442 may be designed such a-Si sublayer and poly-Si sublayer are alternately deposited by changing process parameters, e.g., the flow rates and durations for silicon-containing precursor, and carrier gas; chamber temperature, substrate temperature, chamber pressure, RF frequencies, and RF powers for a-Si deposition and poly-Si deposition.

Typically there will be a user interface associated with the system controller 442. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 442. The signals for controlling the process are output on the analog and digital output connections of the system 400.

The system software may be designed or configured in many different ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code. For example, the system software may be designed such that a program or sections of a program includes performing alternating depositions of a-Si sublayer and poly-Si sublayer by changing the flow rates and durations for silicon-containing precursor, and carrier gas; temperature; chamber pressure; RF frequencies; and RF powers for a-Si deposition and poly-Si deposition.

In some implementations, a system controller 442 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 442, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 442, in some implementations, may be a part of or coupled to a computer that is integrated with, coupled to the system, otherwise networked to the system, or a combination thereof. For example, the system controller 442 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The system controller 442 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### EXAMPLES

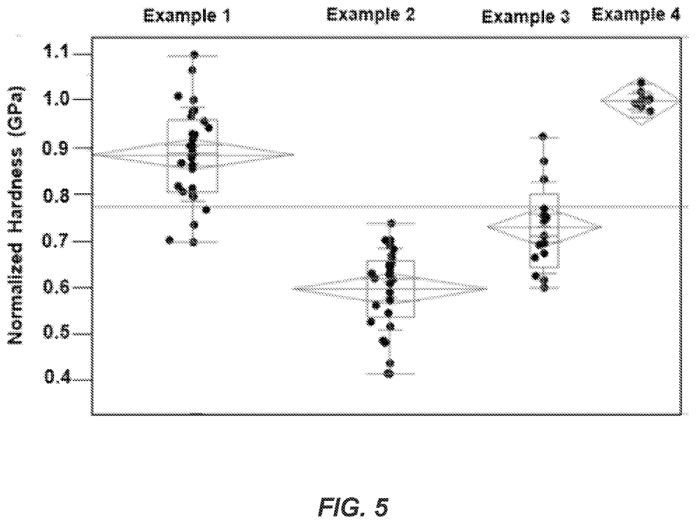

FIG. 5 shows comparison of normalized hardness for four examples including various silicon thin films deposited by PECVD and a silicon substrate. Hardness was measured under identical measurement conditions. Example 1 is a hydrogenated amorphous silicon (a-Si:H) sublayer prepared by PECVD on a substrate. Example 2 is a composite nanocrystalline silicon layer prepared on a substrate according to some embodiments. Example 3 is poly-Si sublayer prepared by PECVD on a substrate. Example 4 is silicon substrate. Measured hardness data for Examples 1-3 are normalized to the measured hardness for Example 4. For normalization, hardness for Example 4 (silicon substrate) are set to 1.0.

The composite nanocrystalline silicon layer in Example 2 has the lowest average normalized hardness of about 0.59. The average normalized hardness for poly-Si sublayer (Example 3) was about 0.73, which was more than 22% higher than that of the composite nanocrystalline silicon layer (Example 2). The a-Si:H sublayer (Example 1) had average normalized hardness of about 0.89, which is about 49% greater than the composite nanocrystalline silicon layer (Example 2). As explained above, average normalized hardness for silicon substrate (Example 4) was set to 1.0. Hardness was measured using a nanoindentation technique described herein. Of all examples tested, the composite nanocrystalline silicon layer showed lowest hardness value, which corresponds to the softest material tested. Using the composite nanocrystalline silicon layer as backside layer of the substrate may be advantageous in extending the life of ESC by reducing or eliminating the damage on the table surface from contacting the substrate backside.

### Conclusion

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1-10. (canceled)

11. A method of forming a composite nanocrystalline silicon layer, the method comprising:
(a) depositing a polycrystalline silicon sublayer directly or indirectly on a substrate;
(b) depositing an amorphous silicon sublayer on the polycrystalline silicon sublayer; and
(c) repeating (a) and (b) one or more times.

12. The method of claim 11, wherein the polycrystalline silicon sublayer or the amorphous silicon layer is deposited by chemical vapor deposition, plasma assisted chemical vapor deposition, atomic layer deposition, plasma assisted atomic layer deposition, or epitaxial growth.

13. The method of claim 11, wherein (c) is performed at least two times.

14. The method of claim 11, wherein the polycrystalline silicon sublayer and the amorphous silicon sublayer are deposited on a backside of the substrate.

15. The method of claim 11, wherein the thickness ratio of the polycrystalline silicon sublayer to the amorphous silicon sublayer is about 0.2 to 3.0.

16. The method of claim 11, wherein the thickness of the amorphous silicon sublayer or the polycrystalline silicon sublayer is about 5 to 50 nm.

17. The method of claim 11, wherein the amorphous silicon sublayer or the polycrystalline silicon sublayer is deposited at a temperature of about 200-600° C.

18. The method of claim 11, wherein the amorphous silicon sublayer or the polycrystalline silicon sublayer is deposited at a pressure of about 1-9 Torr.

19. The method of claim 11, wherein the amorphous silicon sublayer or the polycrystalline silicon sublayer is deposited at an RF power of about 100-500 watts per station.

20. The method of claim 11, wherein the amorphous silicon sublayer or the polycrystalline silicon sublayer is deposited at an RF frequency of about 13.56 MHz or about 27 MHz.

21. The method of claim 11, wherein the composite nanocrystalline silicon layer has a hardness of about 9 GPa or less.

22. The method of claim 11, wherein the composite nanocrystalline silicon layer has a surface roughness of about 0.2 to about 10 nm.

23. An apparatus comprising:
a reaction chamber;
a pedestal for supporting a substrate comprising a front side and a backside in the reaction chamber during a deposition process;
a gas supply configured to deliver a silicon-containing precursor to the substrate while held by the pedestal;
a radio frequency (RF) power supply for providing power to the showerhead to generate a plasma; and
a controller configured to cause:
(a) depositing a polycrystalline silicon sublayer directly or indirectly on the substrate;
(b) depositing an amorphous silicon sublayer on the polycrystalline silicon sublayer; and
(c) repeating (a) and (b) one or more times.

24. The apparatus of claim 23, wherein the gas supply is fluidly coupled to the pedestal to deliver the silicon-containing precursor to the backside of the substrate.

25. The apparatus of claim 23, wherein the pedestal is configured to deposit the polycrystalline silicon sublayer or the amorphous silicon sublayer on the backside of the substrate.

26. The apparatus of claim 23, wherein the polycrystalline silicon sublayer and the amorphous silicon sublayer are deposited by a plasma enhanced chemical vapor deposition or a plasma enhanced atomic layer deposition.

27. A method comprising:
(a) forming a bow-compensating backside layer on substrate, wherein the backside layer has a surface roughness of about 1-4 nm,
(b) attaching the substrate to a substrate support, and
(c) performing a fabrication operation on the substrate while attached to the substrate support.

28. The method of claim 27, wherein the bow-compensating layer has a hardness of about 10 GPa or less.

29. The method of claim 27, wherein the substrate support is a clamp or a chuck.

30. The method of claim 27, wherein the substrate support is a lithography table for a UV or EUV lithography system.
